(19) United States
(12) Patent Application Publication
(10) Pub. No.: US 2025/0315566 A1
(43) Pub. Date: Oct. 9, 2025

(54) Systems And Methods For Comparing Cell Staining In A Simulated Cell

(71) Applicant: Life Technologies Corporation, Carlsbad, CA (US)

(72) Inventors: Steven Titus, Carlsbad, CA (US); Kincade Bertrand, Carlsbad, CA (US); Ross Cargill, Edinburgh (GB); Martin Coane, Edinburgh (GB); Robert Davison, Rockford, IL (US); Jacob McKay, Pittsburgh, PA (US); Iain Simpson, Pittsburgh, PA (US)

(21) Appl. No.: 18/628,000

(22) Filed: Apr. 5, 2024

(51) Int. Cl. G06F 30/20; G06F 3/04842

(52) U.S. Cl. CPC G06F 30/20; G06F 3/04842

(57) ABSTRACT

A method can comprise receiving, at a user interface, at least one user selection associated with cell staining. The method can further comprise determining a first product associated with staining a first portion of a cell. The method can further comprise determining, a first simulated view of a stained cell stained with the first product, wherein the first simulated view of the stained cell comprises a portion of the cell highlighted in a particular color. The method can further comprise determining a first emission spectrum associated with the first product and the particular color. The method can further comprise displaying, at the user interface, at least one of the first simulated view of the stained cell and the first emission spectrum associated with the first simulated view of the stained cell.

### TECHNICAL FIELD

The present disclosure relates to the field of cell staining, including systems and methods for visualizing the effect of cell staining products using a virtual cell.

### BACKGROUND

Staining cells to enhance visualization of an entire cell or a part of a cell is common practice among biological scientists. Without adding a stain to enhance a particular portion of a cell, it can be difficult to distinguish an area of the cell of interest from surrounding regions.

There are many products available to stain cells, and it is not always intuitive which product is the best for a particular application. Additionally, it can be difficult to determine whether two or more cell staining products can be used simultaneously without causing visual interference.

As a consequence, determining which cell staining product to use, or which cell staining products to use together, is frequently done via trial and error. Cells are physically stained using the products, and users analyze the outcome to determine which staining products, or combinations of staining products, are most effective for the user's needs. Such trial and error, however, can be time consuming and expensive. Further, cells can be lost during the experimental preparation, and products can be wasted during the trial and error analysis. Accordingly, there is a need to effectively identify which staining products are desirable for use in a particular cell and for a particular system, and there is a particular need to do so without wasting time, money, and inventory.

### SUMMARY

To address the constraints above, the present disclosure provides a system and method for visualizing the effect of different cell staining products on a cell, without requiring cells to actually be stained. The present system shows a model of an example cell, and individual portions of the model cell can be altered to show the outcome of using a particular cell staining product to stain an actual cell. The virtual cell staining can occur in real-time, essentially eliminating any time wasted by a user in determining which cell staining product should be used for a particular experiment. The virtual cell staining also prevents the waste of any cells and cell staining product, reducing cost to the user. Additionally, the user can mix and match multiple types of cell staining products to produce a virtually stained cell with multiple portions of the cell stained by different products. Therefore, the user can be able to determine precisely which products should be used in an experiment before even beginning the experiment. Moreover, the user can compare among hundreds, or even thousands, or different cell staining products virtually without having to stockpile an unnecessary quantity of different products.

In one aspect, the present disclosure provides a method, comprising: receiving, at a user interface, at least one user selection associated with cell staining; determining, based on the at least one user selection, a first product associated with staining a first portion of a cell; determining, based on the user selection of the first product, a first simulated view of a stained cell stained with the first product, wherein the first simulated view of the stained cell comprises a portion of the cell highlighted in a particular color; determining, based on the first product, a first emission spectrum associated with the first product and the particular color; and displaying, at the user interface, at least one of the first simulated view of the stained cell and the first emission spectrum associated with the first simulated view of the stained cell.

The present disclosure also provides a computing device, comprising: one or more processors; and memory storing instructions that, when executed by the one or more processors, cause the computing device to: receive, at a user interface associated with the computing device, at least one user selection associated with cell staining; determine, based on the at least one user selection, a first product associated with staining a first portion of a cell; determine, based on the user selection of the first product, a first simulated view of a stained cell stained with the first product, wherein the first simulated view of the stained cell comprises a portion of the cell highlighted in a particular color; determine, based on the first product, a first emission spectrum associated with the first product and the particular color; and display, at the user interface associated with the computing device, at least one of the first simulated view of the stained cell and the first emission spectrum associated with the first simulated view of the stained cell.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The drawings illustrate generally, by way of example, but not by way of limitation, various aspects discussed in the present document. In the drawings:

FIG. 1 shows an illustrative interface of the virtual cell staining system.

FIG. 2 shows a selection of a cell type in the cell staining system.

FIG. 3 shows a selection of a structure in the cell staining system.

FIG. 4 shows a selection of a channel in the cell staining system.

FIG. 5 shows a selection of a product type in the cell staining system.

FIG. 6 shows a selection of a product in the cell staining system.

FIG. 7 shows an illustrative output and a selection of an instrument configuration in the cell staining system.

FIG. 8 shows an illustrative selection of an options menu in the cell staining system.

FIG. 9 shows an alternative layout of the cell staining system interface.

FIG. 10 shows an output of an illustration of a portion of a stained cell and an output of a spectrum of the portion of the stained cell corresponding to a selected product.

FIG. 11 shows two stained portions of a cell and two corresponding spectra associated with two selected products.

FIG. 12 shows four stained portions of a cell and four corresponding spectra associated with four selected products.

FIG. 13 shows an illustrative computing device.

### DETAILED DESCRIPTION OF ILLUSTRATIVE EMBODIMENTS

The present disclosure can be understood more readily by reference to the following detailed description of desired embodiments and the examples included therein.

Unless otherwise defined, all technical and scientific terms used herein have the same meaning as commonly understood by one of ordinary skill in the art. In case of conflict, the present document, including definitions, will control. Preferred methods and materials are described below, although methods and materials similar or equivalent to those described herein can be used in practice or testing. All publications, patent applications, patents and other references mentioned herein are incorporated by reference in their entirety. The materials, methods, and examples disclosed herein are illustrative only and not intended to be limiting.

The singular forms “a,” “an,” and “the” include plural referents unless the context clearly dictates otherwise.

As used herein, the terms “about” and “at or about” mean that the amount or value in question can be the value designated, or some other value approximately or about the same. It is generally understood, as used herein, that it is the nominal value indicated ±10% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

Unless indicated to the contrary, the numerical values should be understood to include numerical values which are the same when reduced to the same number of significant figures and numerical values which differ from the stated value by less than the experimental error of conventional measurement technique of the type described in the present application to determine the value.

All ranges disclosed herein are inclusive of the recited endpoint and independently of the endpoints. The endpoints of the ranges and any values disclosed herein are not limited to the precise range or value; they are sufficiently imprecise to include values approximating these ranges and/or values.

As used herein, approximating language can be applied to modify any quantitative representation that can vary without resulting in a change in the basic function to which it is related. Accordingly, a value modified by a term or terms, such as “about” and “substantially,” cannot be limited to the precise value specified, in some cases. In at least some instances, the approximating language can correspond to the precision of an instrument for measuring the value. The modifier “about” should also be considered as disclosing the range defined by the absolute values of the two endpoints. For example, the expression “from about 2 to about 4” also discloses the range “from 2 to 4.” The term “about” can refer to plus or minus 10% of the indicated number. For example, “about 10%” can indicate a range of 9% to 11%, and “about 1” can mean from 0.9-1.1. Other meanings of “about” can be apparent from the context, such as rounding off, so, for example “about 1” can also mean from 0.5 to 1.4. Further, the term “comprising” should be understood as having its open-ended meaning of “including,” but the term also includes the closed meaning of the term “consisting.” For example, a composition that comprises components A and B can be a composition that includes A, B, and other components, but can also be a composition made of A and B only. Any documents cited herein are incorporated by reference in their entireties for any and all purposes.

The present disclosure describes generation and presentation of a virtual indication of a cell with one or more portions of the cell stained, with each portion stained based on a selected cell staining product associated with the portion of the cell. The disclosure describes virtual cell staining in general, though more particular examples are provided herein. The following principles can be incorporated in any suitable virtual cell staining system, not simply limited to the examples provided herein.

In one aspect, a generic cell is shown with portions that can be highlighted according to corresponding products used to dye the portions of the generic cell. Though there are numerous types of cells with differing characteristics, there are many portions of a cell that are consistent throughout nearly every cell type. Thus, the generic cell can present an example of a cell that is commonly found in biological systems, and the generic cell can include any number of organelles or other structures that are common to most or all cell types. For example, a generic cell can include a nucleus, a plasma membrane, cytoplasm, a Golgi body, actin, rough and smooth endoplasmic reticulum, ribosomes, and the like.

Numerous products are known, and in use, today for staining portions of cells, both live and fixed. A particular cell staining product can have a first portion that is designed to couple with a specific structure within a cell. For example, the first portion can include an opposite charge to a desired portion of a cell. The opposite charge from the first portion can attract the product to the portion of the cell of interest, and the product can ionically bind to the portion of the cell of interest. Alternatively, or additionally, the first portion of the cell can comprise a receptor that is configured to couple to a particular portion of interest in a cell. Thus, the product can couple, using the receptor, to the portion of interest in the cell.

The products in use today can include a second portion that provides color to the staining product, for example a chromophore. The second portion can be a dye, or the second portion can be fluorescent, for example a fluorescent protein. When a quantity of the staining product is coupled to a particular portion of a cell, the particular portion of the cell can be colored based on the color of the staining product. For example, a green fluorescent protein can be used to tag a nucleus of a cell, and the nucleus of the cell can show up as a green, generally spherical object upon inspection. Accordingly, the disclosure presented herein is designed in a manner to allow for a virtual reproduction of what a cell can look like with any number of, and combination of, stains at any different locations throughout the cell.

Any number of instruments can be used to detect stained cells. For example, an instrument can use a light emitting diode (LED), a laser, or any other known illumination source to illuminate a stained cell. The instruments can comprise any known magnification source to increase the visibility of the stained cell. The instruments can comprise any known image capturing technology to display or save an image of the stained cell. Accordingly, the disclosure presented herein is designed in a manner to allow for users to view a virtual stained cell under conditions that would be present using any number of different instruments known in the art. Users can select from a plurality of instrument configurations and import custom configurations of instruments to support any experiment a user wishes to perform with any combination of cell, stain, and instrument configurations.

The system presented herein can be configured to allow many different degrees of freedom within the sample preparation and selection process. Users can easily compile a plurality of staining products that can be present in a single cell simultaneously and yet provide sufficiently clear staining of different parts of the single cell together. For example, users can be able to determine that staining both a nucleus and a cytoplasm with a green stain can be undesirable due to the similarity in colors between the two portions of the cell. However, the user can determine that staining a nucleus blue and a cytoplasm orange-red can be a suitable combination of stains to produce a desired result. The user can then prepare an experiment using the determined staining products with confidence that the outcome of the experiment will produce viable results. Using the presently disclosed system, users can reduce a cost of procuring useless staining products, reduce wastage of staining product, cells, media, and other sample preparation materials, and the users can reduce time wasted on trial-and-error experimentation to determine suitable combinations of cell staining products.

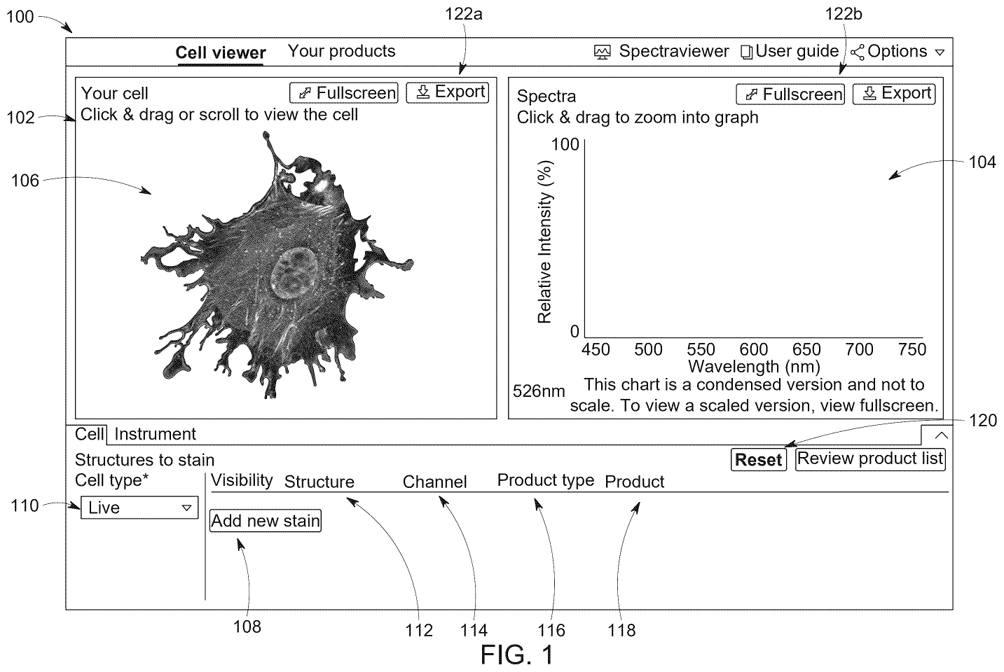

FIG. 1 shows an example user interface 100 associated with testing cell staining products in a manner that provides instant feedback about what a cell stained with the selected product(s) would look like. For example, a portion of the user interface comprises a cell view 102, in which an example cell 106 can be shown. The example cell 106 can initially be shown in gray scale, or in low contrast colors that show the outline of the example cell 106 without providing color highlighting of any particular portion of the example cell 106. As a user adds, removes, or alters selected cell staining products elsewhere on the user interface, the example cell 106 on the cell view 102 can be updated in nearly real-time. For example, if a user selects a new cell staining product that has a cyan color and stains a nucleus of a cell, the example cell 106 can be updated in near real-time to change the color of a nucleus on the example cell 106 to a cyan color associated with the selected cell staining product.

The user interface 100 also comprises a portion associated with a spectra viewer 104. The spectra viewer can comprise a wavelength on an x-axis and a relative intensity on a y-axis. For example, the wavelength may be listed in nanometers and the relative intensity may be listed as a percentage. The spectra viewer 104 can present an example spectrum associated with a particular combination of selected cell staining products, representing the light absorption of the selected cell staining products. The spectra viewer 104 can comprise a range of wavelengths of light similar to the visible spectrum, though near infrared wavelengths can be supported in the spectra viewer 104, longer wavelengths than near infrared can be supported in the spectra viewer 104, near ultraviolet wavelengths can be supported in the spectra viewer 104, or shorter wavelengths than near ultraviolet can be supported in the spectra viewer 104, depending on at least one of a configuration of an experimental design or a range of wavelengths associated with a selected cell staining product.

A user can begin an experiment using the user interface 100 to determine what an outcome of using a particular cell staining product would look like in a real-world cell staining analysis. A user can begin a product selection process by selecting the “add new stain” button 108 to add a portion to the user interface 100 for determining a new cell staining product. Upon selection of the “add new stain” button 108, a series of selectable fields can appear to fine tune options and refine a search for a cell staining product that meets several characteristics. For example, a first characteristic can be related to a cell type. However, though FIG. 1 displays a cell type as a first characteristic, any of the characteristics listed in this disclosure can be a first characteristic. The order of the characteristics can be interchangeable. For example, the cell type characteristic can be a second listed characteristic, a final listed characteristic, or any other position among the characteristics. Moreover, each of the selectable fields can be left blank, or each of the selectable fields can comprise an “any” option, in which the cell staining product selection process is not narrowed by a particular selectable field. For example, a “channel” selectable field can be left blank or filled with the “any” option, in which case the cell staining product selection process will not discard any cell staining products based on an emission channel of the cell staining products.

The selectable cell type area 110 can be shown as a dropdown menu. The cell type area 110 can be a search bar that a user can select and enter a cell type in the cell type search bar. Additionally, or alternatively, the cell type area 110 can support a dropdown menu with a plurality of cell types available for testing. For example, the dropdown menu can comprise cell types such as live cell, fixed cell, fixed/retained cell, and the like. A live cell can represent a living cell that can dynamically change during an experimental analysis. A fixed cell can be a cell that is locked in place to prevent the cell from moving or otherwise changing prior to or during the experimental analysis. For example, a fixed cell can be dead, in the sense that the cell is no longer undergoing any active cellular processes. Based on the type of cell type selected, other portions of the product selection process can be altered. For example, certain cell staining products can only be available for use with live cells. Accordingly, if a user selects a fixed cell type, the system disclosed herein may not display any of the cell staining products that are only available for use with live cells. Some cell staining products can be available for use in multiple cell types or even in all cell types. The user can select a structure of the cell with which the cell staining product is to interact.

A selectable structure area 112 can list a plurality of portions of a cell that can be bound with a cell staining product. For example, structures within a cell that are commonly stained include, but are not limited to: actin, autophagosome, cytoplasm, endoplasmic reticulum, endosomes, Golgi, lysosomes, mitochondria, nucleus, peroxisome, plasma membrane, tubulin, and any other cell structure that is known in the art of cell staining. The selectable structure area 112 can be a search bar that a user can select and enter a cell structure in the cell structure search bar. Additionally, or alternatively, the cell structure area 112 can support a dropdown menu with a plurality of cell structures available for staining. The dropdown menu can list each of the possible cell structures that can be stained as part of a cell staining analysis.

A selectable channel area 114 can list a plurality of emission channels that a user can choose from when staining a cell. The emission channel can comprise a color. For example, the emission channel area 114 can be a search bar that a user can select and enter an emission channel in the emission channel search bar. For example, a user can select the search bar and enter a number, for example a number corresponding to a wavelength of light that represents an emission channel associated with a cell staining product. The user can select the search bar and enter a color that represents an emission channel associated with a cell staining product. Additionally, or alternatively, the emission channel area 114 can support a dropdown menu with a plurality of emission channels for a user to choose from. For example, the dropdown menu can list CFP (445/90) Cyan, GFP (525/70) Green, Cy3 (585/50) Orange, Texas Red (625/30) Red, Cy5 (670/30) Far Red, Cy7 (725/50) Near IR, or any other suitable emission channel for use in cell staining analysis.

A selectable product type area 116 can list a plurality of product type options that a user can choose from to stain a cell. The product type options can comprise different types of molecules or other products that interact and bind with cell structures. For example, a product type can be a dye. The dye can enter a cell, for example, through a cell's outer membrane, and the dye can bind with a particular portion of the cell. For example, the dye can carry a particular charge, such as a positive charge or a negative charge, and the dye can selectively bind to a portion of the cell with an opposite charge. For example, a dye with a positive charge can selectively bind a cell wall that carries an overall negative charge. A product type can be an antibody. The antibody can comprise a molecule with a portion that is selectively able to bind to particular structures in a cell. For example, an antibody can be selectively able to bind to particular portions of a nucleus in a cell. Therefore, the antibody can be introduced to the cell, and the antibody can bind to the nucleus of the cell. The antibody can also be configured to produce fluorescence, have a visible color, or be otherwise visible within a cell under experimental conditions. Therefore, cell staining antibodies can be introduced to a cell, the cell staining antibodies can selectively bind to a portion of the cell to which the antibodies are attuned, and the portion of the cell can be visible during a cell staining analysis due to a color or fluorescence associated with the antibody.

A selectable product area 118 can list a plurality of products that meet the conditions of the rest of the selected areas. For example, the product area can be a search bar, and a user search for a particular product by entering the name of, or a portion of the name of, the product. The selectable product area 118 can be a dropdown menu. The system disclosed herein can be configured with hundreds or thousands of products. However, it can be inconvenient or inefficient for the system to present a user with hundreds or thousands of different product options for use in a cell staining analysis. Therefore, as the user selects options in the other selectable areas, the dropdown menu of the product area 118 can be narrowed to only present product options that meet the criteria described in the other selectable areas.

For example, if a user selects a structure—nucleus, a product type—dye/reporter, and an emission channel—GFP (525/70) Green, the selectable product area 118 can show a dropdown menu that lists products compatible with staining a nucleus using a GFP (525/70) emission channel dye/reporter. There can only be a single product that matches the selected options. There can be a plurality of products that match the selected options. The user can select from any of the available product options. The user can adjust any of the previous selectable areas to change a list of products available for selection in the product area 118.

A user can desire to choose a new product with new selected features. The user can select the reset button 120 to remove previously determined selectable areas and a previously selected product. The reset button 120 can return the user interface 100 to substantially the same state as upon original initiation of the user interface 100. For example, a user can have selected a product associated with dyeing a nucleus green. The user can desire to search for a different product associated with dyeing a cell membrane red. The user can select the reset button 120 to remove the previous selections and output of the green nucleus of the cell in the cell view 102. The system can receive new selections of a cell type, structure, emission channel, product type, product, and the like related to dyeing a cell membrane red. The system can output a list of products that match the criteria received by the system. The system can receive a selection of a particular product. The system can output the cell 106 with an indication of the cell membrane dyed red.

The system comprises additional commands that can manipulate either the cell view 102, the spectra view 104, or both the cell view 102 and the spectra view 104. For example, a fullscreen cell view button and an export cell view button 112a are shown near the cell view 102. A user determine a cell staining experiment with one or more cell staining products, and the system can output the cell 106 with stained portions of the cell 106 according to the selected products. The user can desire to view the stained cell 106 in more detail. The system can receive an indication of a user selection of the fullscreen button 122a, and the stained cell 106 can expand to fill substantially all of the user interface 100. Alternatively, or additionally, the user can desire to save the stained cell 106 for later sharing or viewing. The system can receive a user input associated with the export button 122a. The system can prepare a file of the stained cell 106 according to the cell staining products selected. The user can save the file of the stained cell to a location, for example a local drive of the user's computing device, for later viewing or sharing.

The system comprises similar commands for manipulating the spectra view 104. Though not shown in FIG. 1, upon receiving a product selection, the system can output a stained version of the cell 106, and the system can also output a spectra view associated with the relative absorption of light associated with each of the products shown in the stained cell 102. The spectra view 104 can be manipulated in a similar manner as the cell view 102. For example, the system can receive an indication that a user selected a fullscreen button associated with the spectra view 104. The system can expand the spectra to fill substantially all of the user interface 100. Alternatively, or additionally, the system can receive a user input associated with the export button 122b. The system can prepare a file of the spectra associated with the stained cell 106 according to the cell staining products selected. The user can save the file of the spectra to a location, for example a local drive of the user's computing device, for later viewing or sharing.

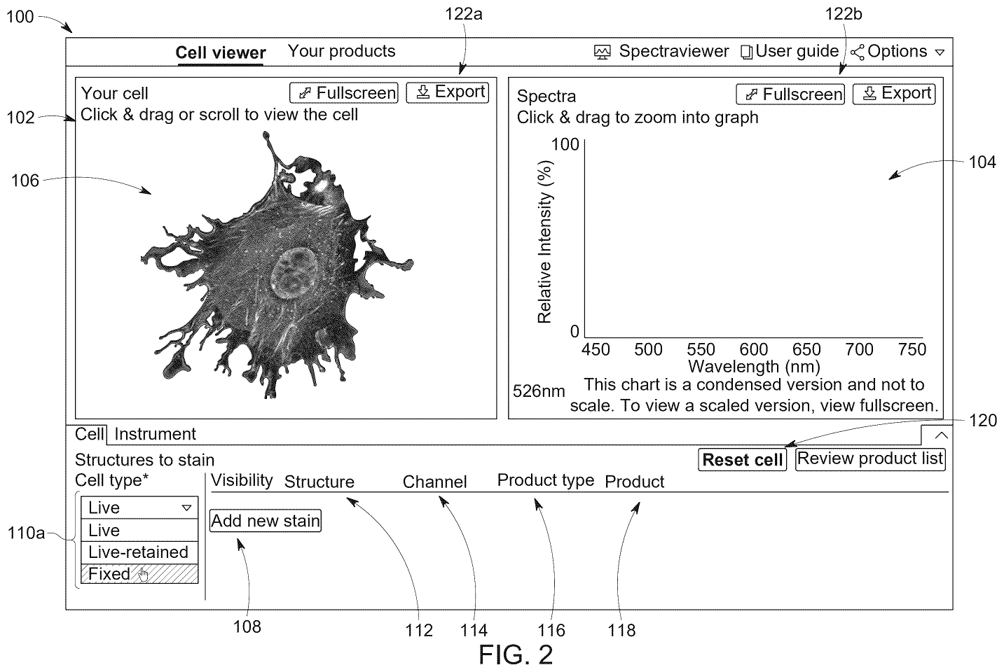

FIG. 2 shows a similar user interface 100 but with added detail regarding the cell type selectable area 110. In FIG. 2, the selectable cell type area 110 is shown as a dropdown menu 110a. The dropdown menu presents each option for a cell type associated with the cell staining experimental analysis. For example, the cell type area dropdown menu 110a can present options for live, live/retained, fixed, fixed/retained, or any other option known to a person of ordinary skill in the art. A selection of a particular cell type can have downstream effects on the options available in the other selectable areas. For example, certain products can only be available for use in a live cell, while certain other products can only be available for use in a fixed cell. Upon selection of a live cell type at area 110a, the system can determine that products associated with the fixed cell type may not be presented for the particular product selection process.

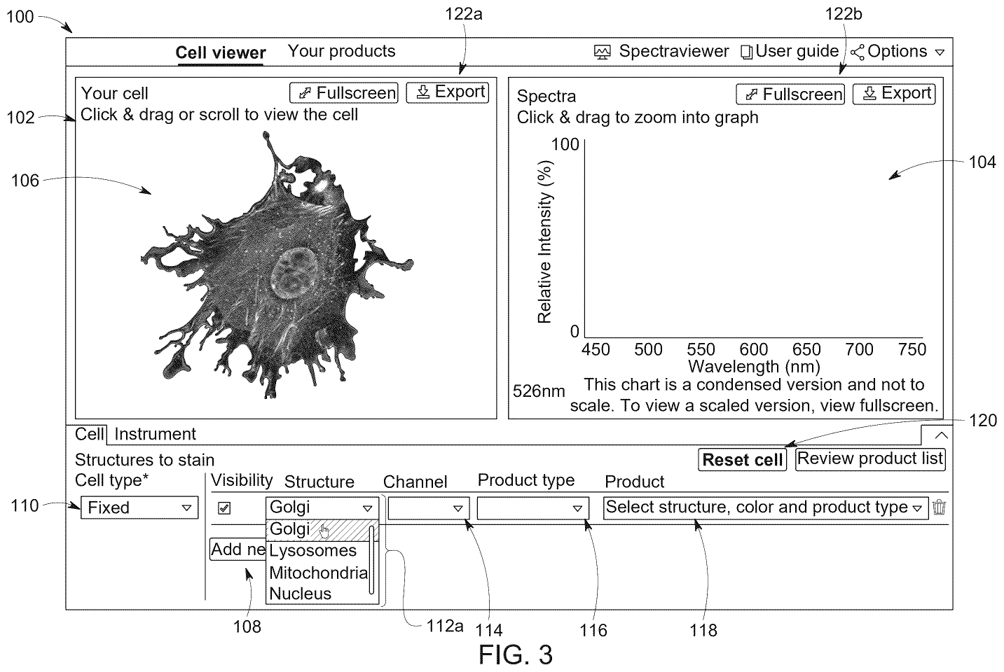

FIG. 3 shows a similar user interface 100 but with added detail regarding the structure selectable area 112. In FIG. 3, the selectable structure area 112 is shown as a dropdown menu 112a. The dropdown menu 112a presents each option for a structure associated with the cell staining experimental analysis. For example, the structure area dropdown menu 112a can present options for actin, autophagosome, cytoplasm, endoplasmic reticulum, endosomes, Golgi, lysosomes, mitochondria, nucleus, peroxisome, plasma membrane, tubulin, or any other option known to a person of ordinary skill in the art. A selection of a particular structure can have downstream effects on the options available in the other selectable areas. For example, certain products can only be available for use in staining a nucleus, while certain other products can only be available for use in staining cytoplasm. Upon selection of a nucleus at area 112a, the system can determine that products associated with the cytoplasm may not be presented for the particular product selection process.

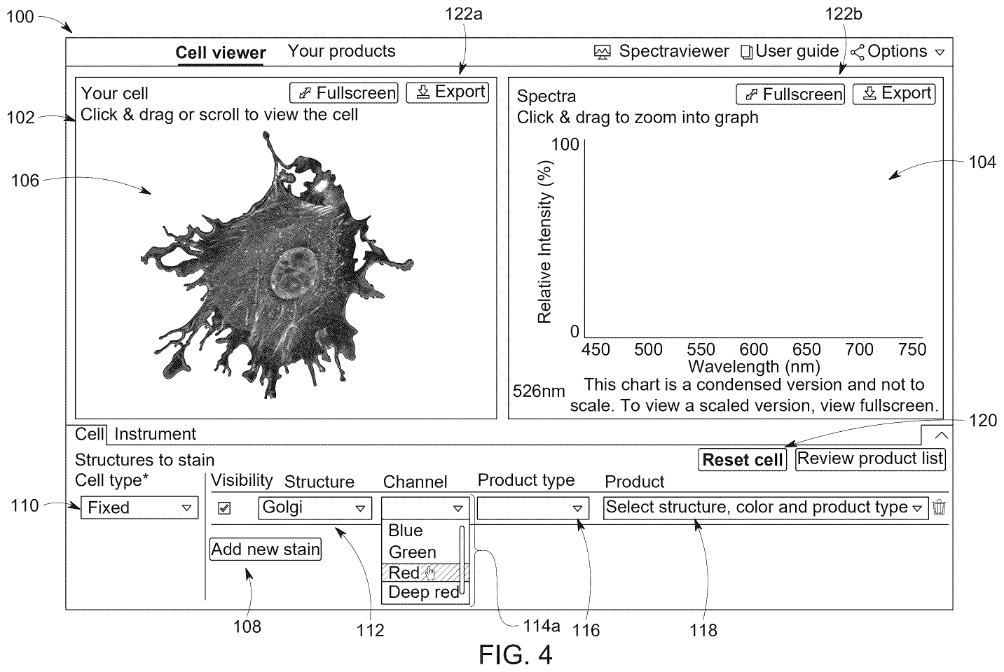

FIG. 4 shows a similar user interface 100 but with added detail regarding the emission channel selectable area 114. In FIG. 4, the selectable emission channel area 114 is shown as a dropdown menu 114a. The dropdown menu 114a presents each option for an emission channel associated with the cell staining experimental analysis. For example, the emission channel area dropdown menu 114a can present options for CFP (445/90) Cyan, GFP (525/70) Green, Cy3 (585/50) Orange, Texas Red (625/30) Red, Cy5 (670/30) Far Red, Cy7 (725/50) Near IR, or any other emission channel known to a person of ordinary skill in the art. A selection of a particular emission channel can have downstream effects on the options available in the other selectable areas. For example, certain products can only be available in CFP (445/90) Cyan, while certain other products can only be available in Cy5 (670/30) Far Red. Upon selection of CFP (445/90) Cyan at area 114a, the system can determine that products associated with Cy5 (670/30) Far Red may not be presented for the particular product selection process.

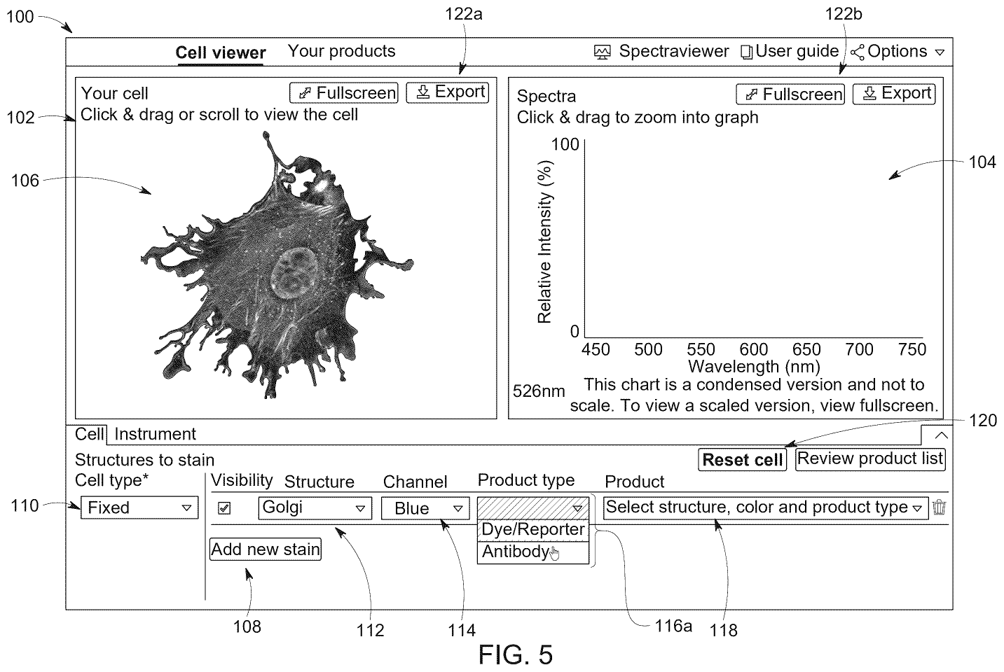

FIG. 5 shows a similar user interface 100 but with added detail regarding the product type selectable area 116. In FIG. 5, the selectable product type area 116 is shown as a dropdown menu 116a. The dropdown menu 116a presents each option for a product type associated with the cell staining experimental analysis. For example, the product type area dropdown menu 116a can present options for a dye, an antibody, or for any other option known to a person of ordinary skill in the art. A selection of a particular product type can have downstream effects on the options available in the other selectable areas. For example, certain products can only be available as dyes, while certain other products can only be available as antibodies. Upon selection of a dye at area 116a, the system can determine that products associated with an antibody may not be presented for the particular product selection process.

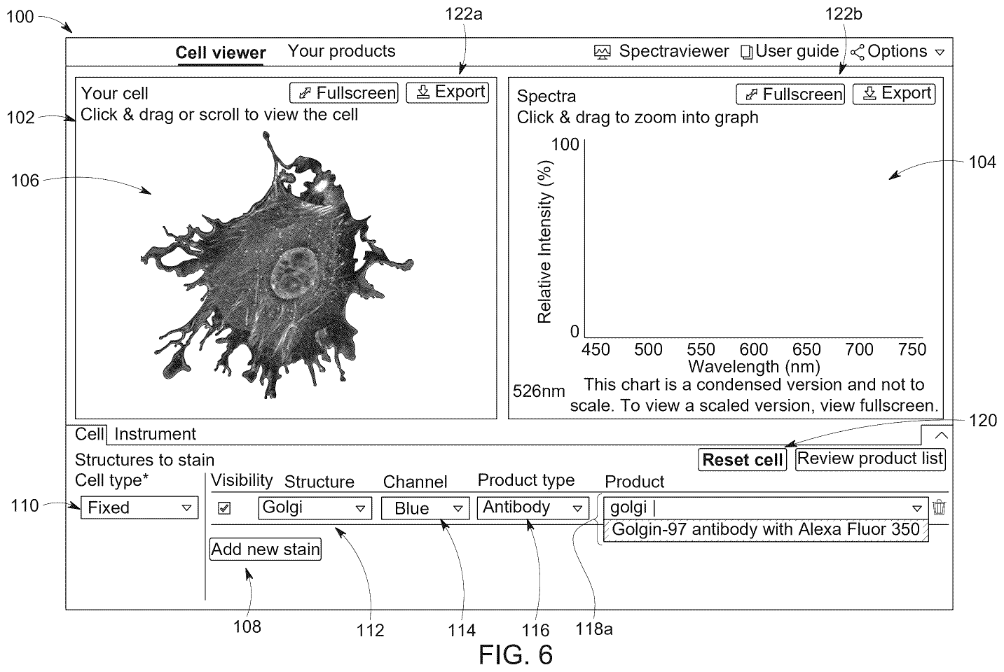

FIG. 6 shows a similar user interface 100 but with added detail regarding the product selectable area 118. In FIG. 6, the selectable product area 118 is shown as a dropdown menu 118a. The dropdown menu 118a presents each option for a product associated with the cell staining experimental analysis according to the other selections. For example, the product area dropdown menu 118a can present one or more products associated with staining a cell according to the other selections of the cell type, structure, emission channel, product type, and the like. A plurality of products can meet the criteria selected in the previous selectable areas, and the system can present the plurality of products in the dropdown menu 118a for a user to select from. The system can be associated with a database comprising numerous cell staining products, and the system can present any one of the products from the database for review and selection by a user for a cell staining experiment. The database can comprise proprietary cell staining products, generically available cell staining products, cell staining products offered for use by competing producers, and the like. Any cell staining product known to one of ordinary skill in the art can be stored in the database, and the system can present a selection of a plurality of cell staining products in response to receiving selections of particular desired characteristics from a user. In this manner, the system can substantially narrow down the list of products a user must sort through to determine which product is right for a particular cell staining experiment, and the user can quickly review the subset of products presented in the product dropdown menu 118a without wasting time reviewing other products that do not meet the criteria desired by the user. The user can update one or more of the other selectable areas, such as the cell type, structure, product type, emission channel, or the like, and the system can nearly instantaneously update the products offered for review in the product dropdown menu 118a. The system can receive an indication of a user selection of a particular product from the products presented at the product dropdown menu 118a. The system can receive an indication of a selection of a review product button on the user interface 100.

Upon receiving an indication of a selection of a particular product and an indication of a request to review the product, the system can present another interface with a product description associated with the selected product. For example, the system can receive an indication of a user selection of acridine orange and an indication of a request to review a product listing. The system can present a new user interface with information regarding acridine orange. For example, the new user interface can present a product description of acridine orange, a packaging associated with acridine orange, and a recommendation for how to use acridine orange.

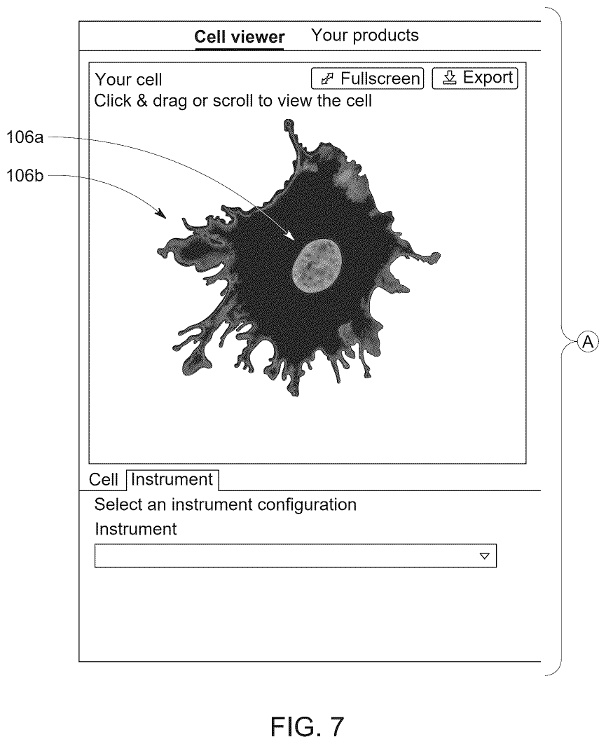

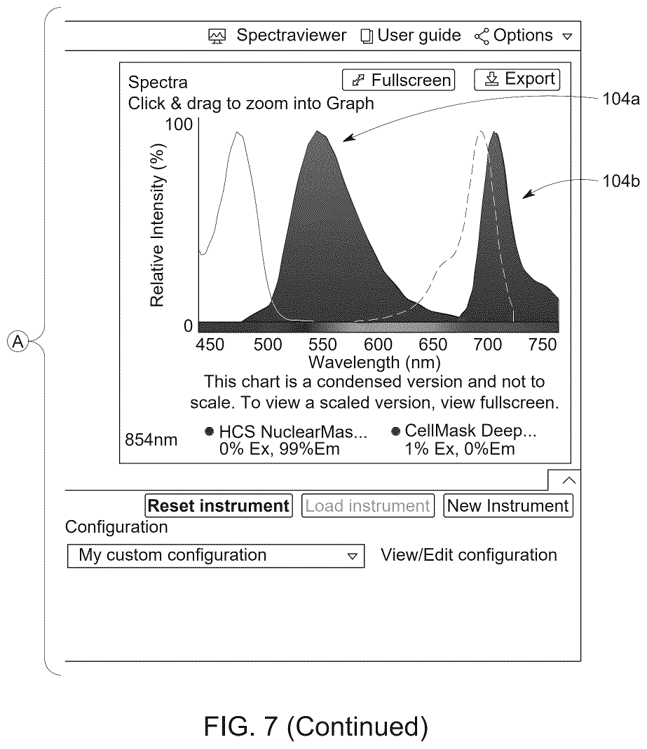

FIG. 7 shows the user interface 100, in which two products have been selected, and in which an instrument configuration is being adjusted. For example, in the cell view 102, the nucleus is stained blue 106a. Correspondingly, in spectra view 104, a spectra shows a portion of a visible spectrum of light related to absorption of light via the stained nucleus 106a. Additionally, cell view 102 shows a stained cell membrane 106b. The stained cell membrane 106b can be stained red using a different product than the product used to stain the nucleus blue. Corresponding to the stained cell membrane 106b, the spectra view 104 shows a portion of the visible light spectrum with an absorption pattern 104b related to the product used to stain the cell membrane. Accordingly, each time a product is selected, the cell view 102 and the spectra view 104 can be updated to show how a cell would look with a portion of the cell stained by the product, in addition to a light spectrum describing the absorption of light related to the product used to stain the cell.

In the bottom half of user interface 100 in FIG. 7, an instrument tab is selected. In FIGS. 1-6 a Cell tab was selected, in which a user can input different characteristics related to a cell staining experiment to receive an output of one or more products associated with the characteristics. In the instrument tab, as shown in FIG. 7, the user can input additional characteristics for the experiment related to the instrument used to capture images of the stained cell. For example, the instrument can be an Agilent Gradient Cycler, a ThermoFisher CellInsight CX5, a ThermoFisher CellInsight CX7 LED Pro, a ThermoFisher CellInsight Cx7 LZR PRO, a ThermoFisher Countess, a ThermoFisher EVOS M5000, a ThermoFisher EVOS M7000, a PerkinElmer Opera Phenix, a Sartorius Incucyte S3, a Sartorius Incucyte Sc5 G/O/NIR, a Sartorius Incucyte Sx5 G/R, a Yokogawa CQ1, a Yokogawa CV7000, a Yokogawa CV8000, or any other instrument configured to capture a stained cell known by one of ordinary skill in the art. Each instrument can be further associated with an instrument configuration. For example, a ThermoFisher CellInsight CX7 LED Pro can be associated with an LED Confocal configuration, while a ThermoFisher CellInsight Cx7 LZR PRO can be associated with a Laser Confocal configuration. Each of the instruments listed herein, and each other instrument known to one of ordinary skill in the art, can be configured with any known configuration by one of ordinary skill in the art.

A user can save a file associated with a particular instrument and configuration for later retrieval. For example, the user can select a load instrument button and the user can import an instrument and configuration file from any number of previously saved files. Therefore, a user can rapidly switch between instruments and configurations to reduce time loss in setting up the experimental conditions from one cell staining experiment to another.

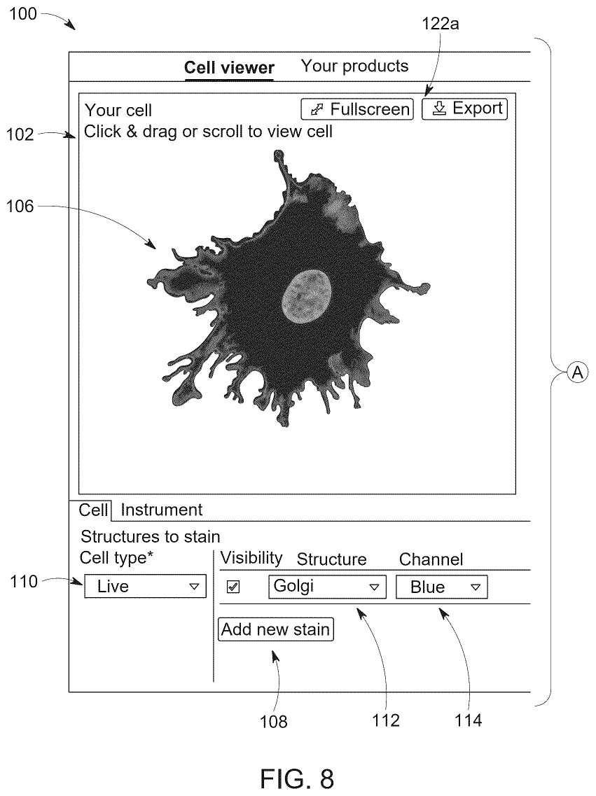

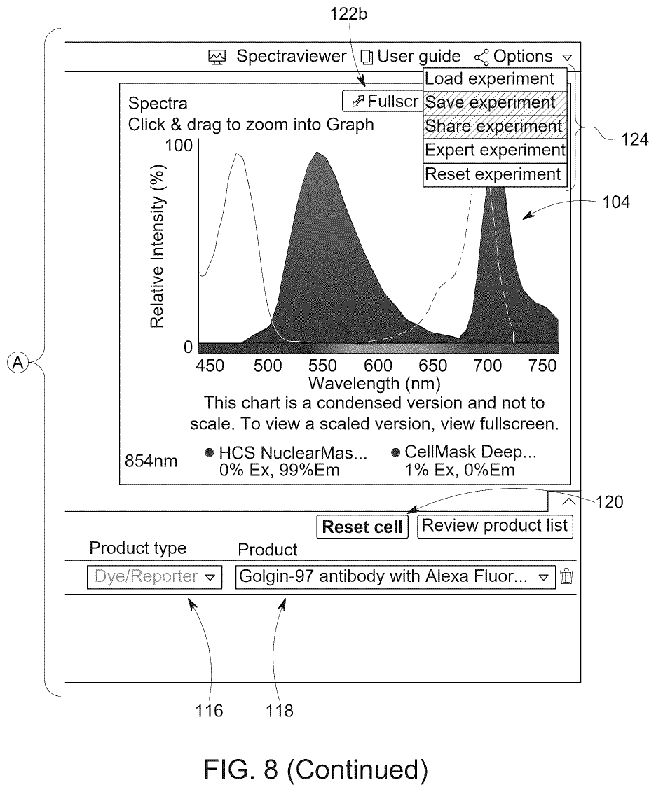

FIG. 8 shows a similar user interface as user interface 100, along with the stained cell and spectra view in FIG. 7. Additionally, FIG. 8 illustrates a dropdown menu 124 for managing experiments. In the dropdown menu 124 a user can load an experiment that was previously saved. For example, a user can load an experiment with a particular instrument and configuration, as well as with a particular set of cell type, structure, emission channel, product type, and product selections, as described in more detail in FIGS. 1-6. The user can save a current experiment. For example, the user can set up a set of selections related to a cell staining product or a plurality of cell staining products, and the user can save the selections to return to. The user can share an experiment with another user by selecting the share experiment button in the dropdown menu 124. For example, the user can be able to share a file with information associated with the experiment via email with another user. The user can be able to export an experiment. For example, the user can export the file to a local drive of the user's computing device for later viewing. The user can reset the experiment from the dropdown menu 124. For example, the user can select the reset experiment button, and all user selections related to cell staining products and instruments can be removed.

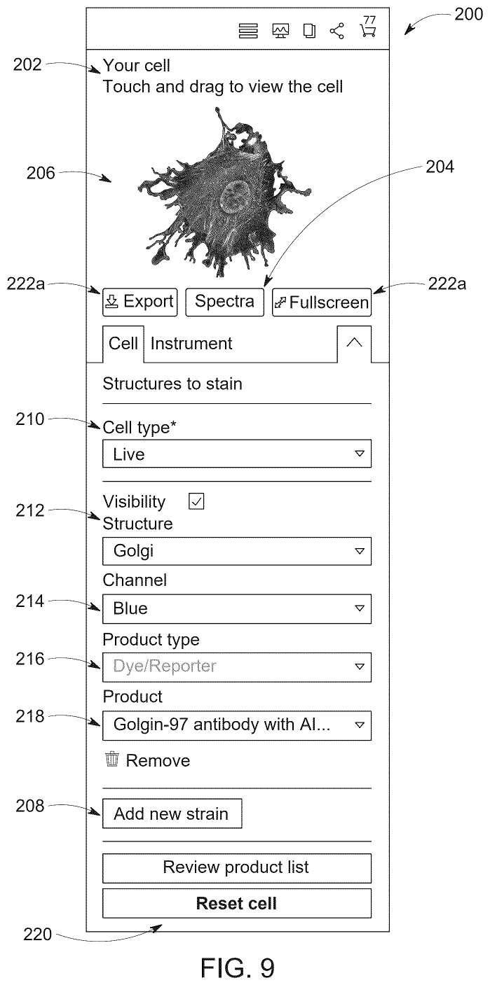

FIG. 9 shows an alternative arrangement of the user interface 100 as user interface 200. User interface 200 can be used, for example, on a mobile device. For example, a user can be able to download an application or navigate to a website associated with the disclosed system on the user's mobile device, and the user interface 200 can be generated on the user's mobile device. The user interface 200 can be more well-suited to using on a small screen than a typical computing device monitor. Though any of the user interfaces, including user interface 100 and user interface 200, can be touch capable, the layout of user interface 200 can be designed to operate more effectively in a touch capable environment than user interface 100.

A portion of the user interface 200 comprises a cell view 202, in which an example cell 206 can be shown. The example cell 206 can initially be shown in gray scale, or in low contrast colors that show the outline of the example cell 206 without providing color highlighting of any particular portion of the example cell 206. As system receives indications to add, remove, or alter selected cell staining products on the user interface 200, the example cell 206 on the cell view 202 can be updated in nearly real-time. For example, if system receives an indication of a user selection of a new cell staining product that has a cyan color and stains a nucleus of a cell, the example cell 206 can be updated in near real-time to change the color of a nucleus on the example cell 206 to a cyan color associated with the selected cell staining product.

The user interface 200 also comprises a portion associated with a spectra view similar to spectra view 104, though the spectra view is not shown in FIG. 9. The system can receive an indication of a selection of spectra view button 204, and the user interface 200 can replace the cell view 202 with a spectra view associated with any selected cell staining products. The spectra view can comprise a wavelength on an x-axis and a relative intensity on a y-axis. For example, the wavelength may be listed in nanometers and the relative intensity may be listed as a percentage. The spectra view can present an example spectrum associated with a particular combination of selected cell staining products, showing a graph of the light absorption of the selected cell staining products across a spectrum of light. The spectra view can comprise a range of wavelengths of light similar to the visible spectrum, though near infrared wavelengths can be supported in the spectra view, longer wavelengths than near infrared can be supported in the spectra view, near ultraviolet wavelengths can be supported in the spectra view, or shorter wavelengths than near ultraviolet can be supported in the spectra view, depending on at least one of a configuration of an experimental design or a range of wavelengths associated with a selected cell staining product.

A user can begin an experiment using the user interface 200 to determine what an outcome of using a particular cell staining product would look like in a real-world cell staining analysis. The user can begin a product selection process by selecting the “add new stain” button 208 to add a portion to the user interface 200 for determining a new cell staining product. Upon selection of the “add new stain” button 208, a series of selectable fields can appear to fine tune options and refine a search for a cell staining product that meets several selected characteristics. For example, a first characteristic can be related to a cell type. However, though FIG. 9 displays a cell type as a first characteristic, any of the characteristics listed in the disclosure can be a first characteristic. The order of the characteristics can be interchangeable. For example, the cell type characteristic can be a second listed characteristic, a final listed characteristic, or any other position among the characteristics. Moreover, each of the selectable fields can be left blank, or each of the selectable fields can comprise an “any” option, in which the cell staining product selection process is not narrowed by a particular selectable field. For example, a “channel” selectable field can be left blank or filled with the “any” option, in which case the cell staining product selection process will not discard any cell staining products based on an emission channel of the cell staining products.

The selectable cell type area 210 can be shown as a dropdown menu. The cell type area 210 can be a search bar that a user can select and enter a cell type in the cell type search bar. Additionally, or alternatively, the cell type area 210 can support a dropdown menu with a plurality of cell types available for testing. For example, the dropdown menu can comprise cell types such as live cell, fixed cell, fixed/retained cell, and the like. A live cell can represent a living cell that can dynamically change during an experimental analysis. A fixed cell can be a cell that is locked in place to prevent the cell from moving or otherwise changing prior to or during the experimental analysis. For example, a fixed cell can be dead, in the sense that the cell is no longer undergoing any active cellular processes. Based on the type of cell type selected, other portions of the product selection process can be altered. For example, certain cell staining products can only be available for use with live cells. Accordingly, if a user selects a fixed cell type, the system disclosed herein may not display any of the cell staining products that are only available for use with live cells. Some cell staining products can be available for use in multiple cell types or even in all cell types. The user can select a structure of the cell with which the cell staining product is to interact.

A selectable structure area 212 can list a plurality of portions of a cell that can be bound with a cell staining product. For example, structures within a cell that are commonly stained include, but are not limited to: actin, autophagosome, cytoplasm, endoplasmic reticulum, endosomes, Golgi, lysosomes, mitochondria, nucleus, peroxisome, plasma membrane, tubulin, and any other cell structure that is known in the art of cell staining. The selectable structure area 212 can be a search bar that a user can select and enter a cell structure in the cell structure search bar. Additionally, or alternatively, the cell structure area 212 can support a dropdown menu with a plurality of cell structures available for staining. The dropdown menu can list each of the possible cell structures that can be stained as part of a cell staining analysis.

A selectable channel area 214 can list a plurality of emission channels that a user can choose from when staining a cell. The emission channel can comprise a color. For example, the emission channel area 214 can be a search bar that a user can select and enter an emission channel in the emission channel search bar. For example, a user can select the search bar and enter a number, for example a number corresponding to a wavelength of light that represents an emission channel associated with a cell staining product. The user can select the search bar and enter a color that represents an emission channel associated with a cell staining product. Additionally, or alternatively, the emission channel area 214 can support a dropdown menu with a plurality of emission channels for a user to choose from. For example, the dropdown menu can list CFP (445/90) Cyan, GFP (525/70) Green, Cy3 (585/50) Orange, Texas Red (625/30) Red, Cy5 (670/30) Far Red, Cy7 (725/50) Near IR, or any other suitable emission channel for use in cell staining analysis.

A selectable product type area 216 can list a plurality of product type options that a user can choose from to stain a cell. The product type options can comprise different types of molecules or other products that interact and bind with cell structures. For example, a product type can be a dye. The dye can enter a cell, for example, through a cell's outer membrane, and the dye can bind with a particular portion of the cell. For example, the dye can carry a particular charge, such as a positive charge or a negative charge, and the dye can selectively bind to a portion of the cell with an opposite charge. For example, a dye with a positive charge can selectively bind a cell wall that carries an overall negative charge. A product type can be an antibody. The antibody can comprise a molecule with a portion that is selectively able to bind to particular structures in a cell. For example, an antibody can be selectively able to bind to particular portions of a nucleus in a cell. Therefore, the antibody can be introduced to the cell, and the antibody can bind to the nucleus of the cell. The antibody can also be configured to produce fluorescence, have a visible color, or be otherwise visible within a cell under experimental conditions. Therefore, cell staining antibodies can be introduced to a cell, the cell staining antibodies can selectively bind to a portion of the cell to which the antibodies are attuned, and the portion of the cell can be visible during a cell staining analysis due to a color or fluorescence associated with the antibody.

A selectable product area 218 can list a plurality of products that meet the conditions of the rest of the selected areas. For example, the product area can be a search bar, and a user search for a particular product by entering the name of, or a portion of the name of, the product. The selectable product area 218 can be a dropdown menu. The system disclosed herein can be configured with hundreds or thousands of products. However, it can be inconvenient or inefficient for the system to present a user with hundreds or thousands of different product options for use in a cell staining analysis. Therefore, as the user selects options in the other selectable areas, the dropdown menu of the product area 218 can be narrowed to only present product options that meet the criteria described in the other selectable areas.

For example, if a user selects a structure—nucleus, a product type—dye/reporter, and an emission channel—GFP (525/70) Green, the selectable product area 218 can show a dropdown menu that lists products compatible with staining a nucleus using a GFP (525/70) emission channel dye/reporter. There can only be a single product that matches the selected options. There can be a plurality of products that match the selected options. The user can select from any of the available product options. The user can adjust any of the previous selectable areas to change a list of products available for selection in the product area 218.

A user can desire to choose a new product with new selected features. The user can select the reset button 220 to remove previously determined selectable areas and a previously selected product. The reset button 220 can return the user interface 200 to substantially the same state as upon original initiation of the user interface 200. For example, a user can have selected a product associated with staining a nucleus green. The user can desire to search for a different product associated with staining a cell membrane red. The user can select the reset button 220 to remove the previous selections and output of the green nucleus of the cell in the cell view 202. The system can receive new selections of a cell type, structure, emission channel, product type, product, and the like related to dyeing a cell membrane red. The system can output a list of products that match the criteria received by the system. The system can receive a selection of a particular product. The system can output the cell 206 with an indication of the cell membrane dyed red.

The system comprises additional commands that can manipulate either the cell view 202, the spectra view 204, or both the cell view 202 and the spectra view 204. For example, a fullscreen cell view button and an export cell view button 212a are shown near the cell view 202. A user can determine a cell staining experiment with one or more cell staining products, and the system can output the cell 206 with stained portions of the cell 206 according to the selected products. The user can desire to view the stained cell 206 in more detail. The system can receive an indication of a user selection of the fullscreen button 222a, and the stained cell 206 can expand to fill substantially all of the user interface 200. Alternatively, or additionally, the user can desire to save the stained cell 206 for later sharing or viewing. The system can receive a user input associated with the export button 222a. The system can prepare a file of the stained cell 206 according to the cell staining products selected. The user can save the file of the stained cell to a location, for example a local drive of the user's computing device, for later viewing or sharing.

The system comprises similar commands for manipulating the spectra view. Though not shown in FIG. 9, upon receiving a product selection and a selection of a spectra view button 204, the system can output a spectra view associated with the relative absorption of light associated with each of the products shown in the stained cell 206. Though not shown, the spectra view can be manipulated in a similar manner as the cell view 202. For example, the system can receive an indication that a user selected a fullscreen button associated with the spectra view. The system can expand the spectra to fill substantially all of the user interface 200. Alternatively, or additionally, the system can receive a user input associated with the export button. The system can prepare a file of the spectra associated with the stained cell 206 according to the cell staining products selected. The user can save the file of the spectra to a location, for example a local drive of the user's computing device, for later viewing or sharing.

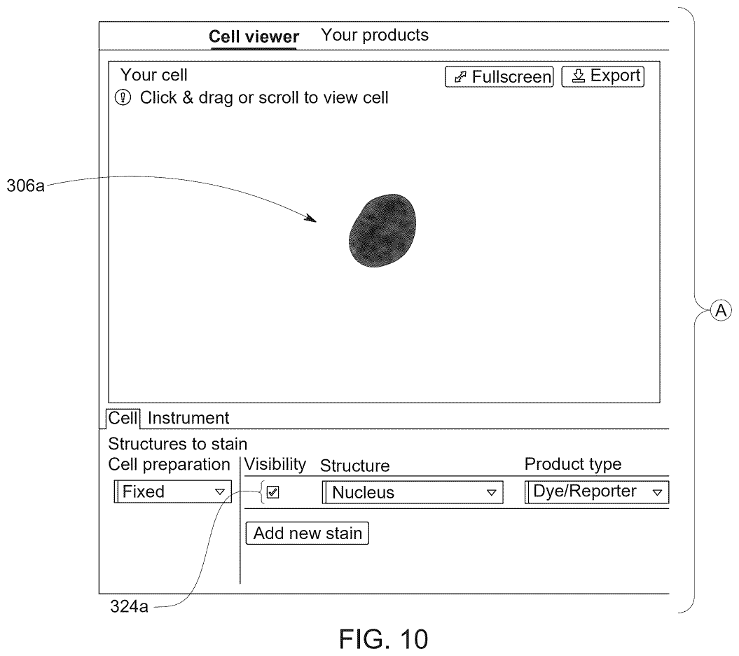

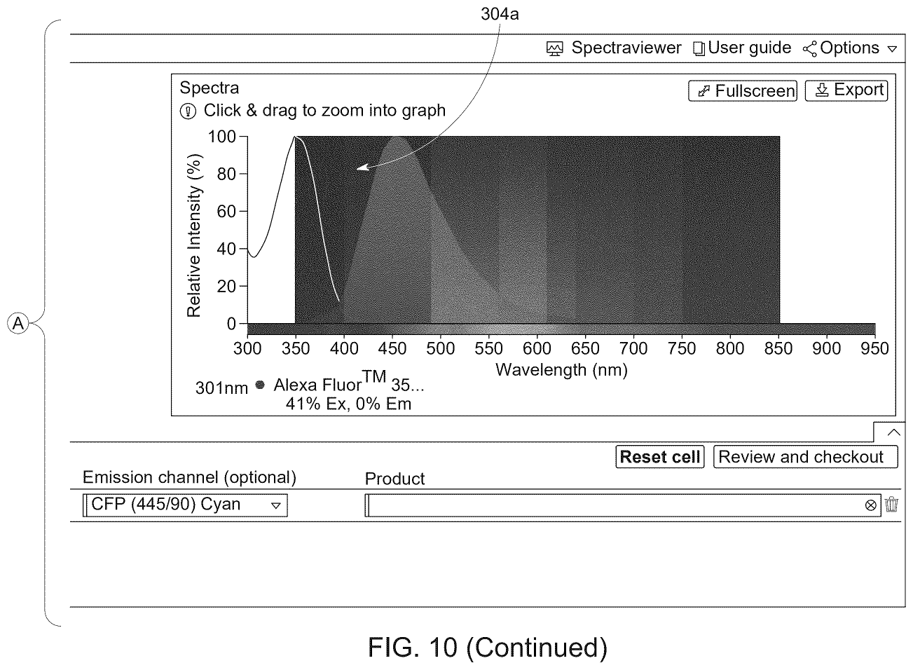

FIG. 10 shows an illustrative example of an selection of a particular cell staining product and the corresponding cell view and spectra view. For example, at step 324a the system disclosed herein can receive a plurality of indications of user selections, ultimately leading to a selection of a product, for example Hoechst 33342, Trihydrochloride, Trihydrate, which is a Cyan dye that can be used to stain a nucleus of a cell. Based on the user's selections of a cell type/preparation, a structure, a product type, and an emission channel, the system can output one or more products matching the criteria in the selected fields. The system can receive an indication of a selection of the Hoechst dye. The system can determine that the cell shown at cell view 102 in FIG. 1 should be presented with a nucleus that is stained blue and with no other structures of the cell present. The system can output an indication of a blue nucleus 306a, and the system can output a corresponding indication of a spectra 304a associated with the blue nucleus of the cell. Accordingly, the interaction between the selectable fields at the lower portion of the user interface can inform the system what to output at the cell view and the spectra view at the top portion of the user interface.

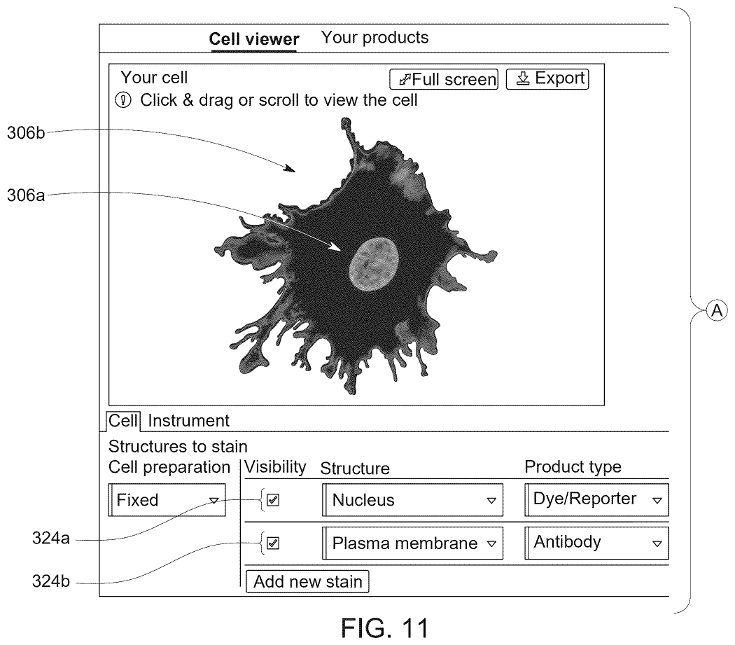

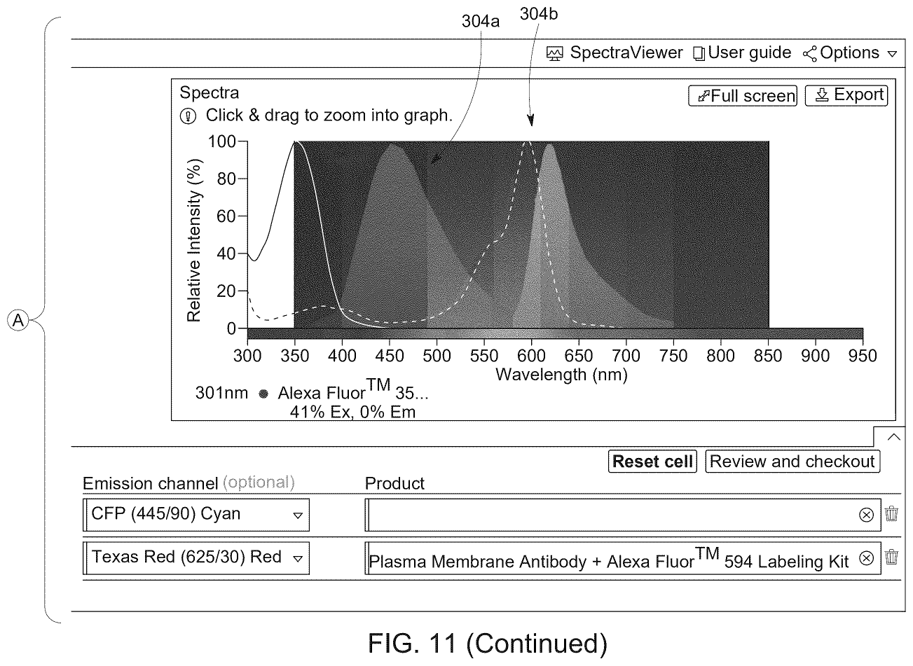

FIG. 11 is similar to the user interface shown at FIG. 10, except FIG. 11 also shows a second product selected to stain a cell membrane of the illustrative cell red. For example, the same Hoechst 33342, Trihydrochloride, Trihydrate is selected at 324a, so the system outputs an indication of a blue nucleus 306a in the cell view and an indication of a spectra 304a associated with the blue dye at the spectra view. Additionally, the system has received indications 324b associated with a second product, including a structure, a product type, an emission channel, and a product. The product is Plasma Membrane Antibody+Alexa Fluor™ 594 Labeling Kit, which is a red antibody type product that can stain a cell membrane red. The system outputs, based on the selections 324b, a cell membrane associated with the illustrative cell in a red color 306b, and the system outputs the corresponding spectra 304b associated with the selected product. Therefore, a user can input several different products at once and see how a cell can look when each of the selected products are used in tandem.

In addition to using the cell staining simulation tool to prepare a simulated view of a cell stained with one or more cell staining products, the cell staining simulation tool can also facilitate purchasing of the products selected in the tool. For example, in FIG. 11 the user selects Hoechst 33342, Trihydrochloride, Trihydrate and Plasma Membrane Antibody+Alexa Fluor™ 594 Labeling Kit to view a simulated cell stained with both products. The user can then select the “Review and checkout” button on the interface to navigate to a different interface (not pictured) to facilitate ordering or purchasing of the selected products. For example, the interface associated with selection of the “Review and checkout” button can present details about the products selected in the cell simulation tool interface, as shown in FIG. 11 for example. The user can be presented with details associated with ordering the Hoechst 33342, Trihydrochloride, Trihydrate. For example, the interface may show a picture of the product, a quantity of the product, a price of the product, a drop down menu to select one or more units of the product for purchase, and the like. The interface can present the user with comparable products. For example, the interface can present the Hoechst 33342, Trihydrochloride, Trihydrate, and the interface can simultaneously present details about products with a similar function, color, price, quantity, or any other details associated with the Hoechst 33342, Trihydrochloride, Trihydrate.

Alternatively, or additionally, the interface can present details associated with Plasma Membrane Antibody+Alexa Fluor™ 594 Labeling Kit or the interface can present similar details associated with any other selected product stored in a database of the cell simulation system. Additionally, the interface can present recommended product pairings. For example, the interface can recommend a particular product for staining a cell membrane based on a selection of the Hoechst 33342, Trihydrochloride, Trihydrate for staining a nucleus. The recommended products may be recommended based on any details associated with the recommended products, for example based on the function of the product, the type of the product, the price of the product, or the interaction between the product and another product. The user can select any one or more of the products from the interface associated with the Review and checkout button, and the selected products can be added to the user's virtual shopping cart. Alternatively, the user can select the products and an order can be immediately placed for the selected products. The user can optionally request a recurring order to be placed for a particular product. For example, the user may use an entire 5 milliliter bottle of Hoechst 33342, Trihydrochloride, Trihydrate in 6 months, and the user can place a recurring order for the Hoechst 33342, Trihydrochloride, Trihydrate to be repeated automatically every 6 months.

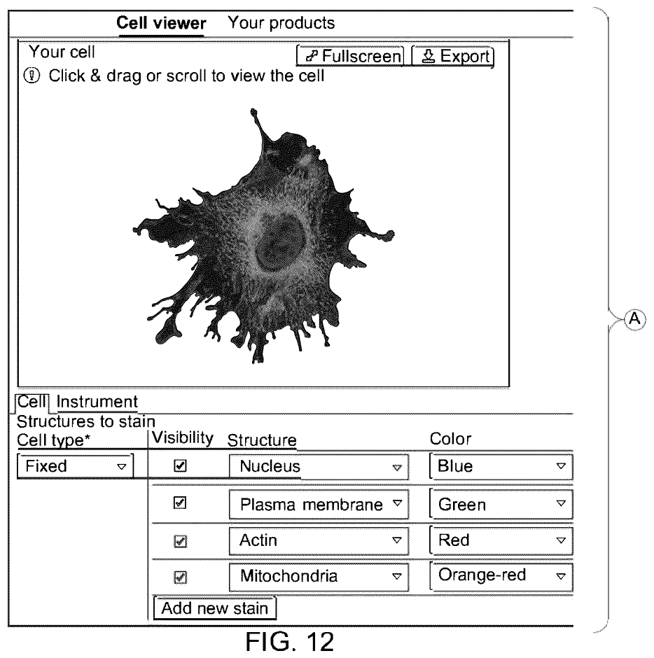

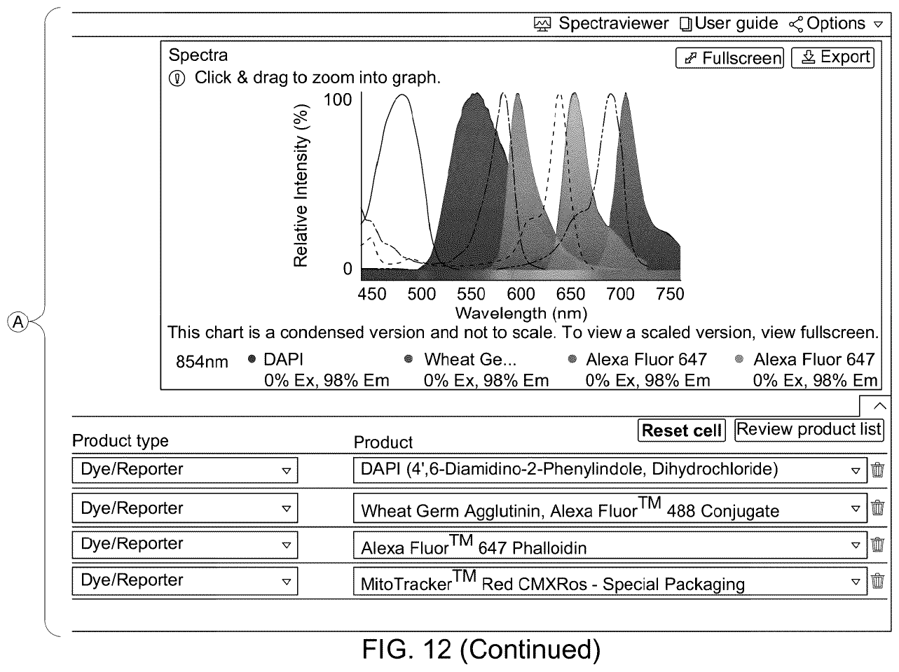

FIG. 12 is similar to FIGS. 10 and 11 but includes four separate cell staining products. Although not substantially functionally different than the multiple product output shown in FIG. 11, FIG. 12 is representative of a larger range of capabilities of the system to output an illustrative cell comprising more than two products at once. For example, the illustrative cell shown in FIG. 12 comprises a blue nucleus, a green plasma membrane, red actin, and orange-red mitochondria. Through the use of the present system, a user can be able to determine that the combination of products shown in FIG. 12 is suitable for an experimental analysis.

For example, the four colors and four structures are all sufficiently different that a user would be able to differentiate the four different stained portions of the cell. Correspondingly, the spectra view shows four separate clusters of light absorption related to the four different colored cell staining products. In another example, a user can be able to use the system to determine that three separate products that all use green fluorescent protein to stain different portions of a cell may not be reliably used in tandem due to the overlapping color. Furthermore, even if two products have a different color in theory, the two products may not be distinguishable from one another in an experimental analysis, and using the present system to determine that two different colored products are not compatible can help save time and money for users.

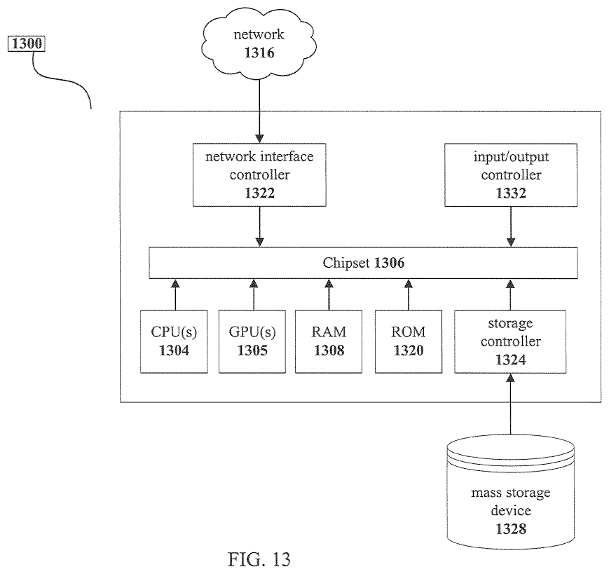

FIG. 13 shows an example computing device 1300. The example computing device 1300 can be used to implement any of the various systems or entities shown in FIGS. 1-12, including a database associated with the system, for example a central server or a central server database. That is, the computing device 1300 shown in FIG. 13 can comprise any smartphone, server computer, workstation, access point, router, gateway, tablet computer, laptop computer, notebook computer, desktop computer, personal computer, network appliance, PDA, e-reader, user equipment (UE), mobile station, fixed or mobile subscriber unit, pager, wireless sensor, consumer electronics, or other computing device, and can be utilized to execute any aspects of the methods and apparatus described herein, such as to implement any of the systems described in FIGS. 1-12.

The computing device 1300 can comprise a baseboard, or “motherboard,” which is a printed circuit board to which a multitude of components or devices can be connected by way of a system bus or other electrical communication paths. One or more central processing units (CPUs or “processors”) 1304 can operate in conjunction with a chipset 1306. The CPU(s) 1304 can be standard programmable processors that perform arithmetic and logical operations necessary for the operation of the computing device 1300.

The CPU(s) 1304 can perform the necessary operations by transitioning from one discrete physical state to the next through the manipulation of switching elements that differentiate between and change these states. Switching elements can generally comprise electronic circuits that maintain one of two binary states, such as flip-flops, and electronic circuits that provide an output state based on the logical combination of the states of one or more other switching elements, such as logic gates. These basic switching elements can be combined to create more complex logic circuits including registers, adders-subtractors, arithmetic logic units, floating-point units, or the like.

The CPU(s) 1304 can be augmented with or replaced by other processing units, such as GPU(s) 1305. The GPU(s) 1305 can comprise processing units specialized for but not necessarily limited to highly parallel computations, such as graphics and other visualization-related processing.

A chipset 1306 can provide an interface between the CPU(s) 1304 and the remainder of the components and devices on the baseboard. The chipset 1306 can provide an interface to a random-access memory (RAM) 1308 used as the main memory in the computing device 1300. The chipset 1306 can provide an interface to a computer-readable storage medium, such as a read-only memory (ROM) 1320 or non-volatile RAM (NVRAM) (not shown), for storing basic routines that can help to start up the computing device 1300 and to transfer information between the various components and devices. ROM 1320 or NVRAM can also store other software components necessary for the operation of the computing device 1300 in accordance with the aspects described herein.

The computing device 1300 can operate in a networked environment using logical connections to remote computing nodes and computer systems of the system 100. The chipset 1306 can comprise functionality for providing network connectivity through a network interface controller (NIC) 1322. A NIC 1322 can be capable of connecting the computing device 1300 to other computing nodes over the system. It should be appreciated that multiple NICs 1322 can be present in the computing device 1300, connecting the computing device to other types of networks and remote computer systems. The NIC 1322 can be configured to implement a wired local area network technology, such as IEEE 802.3 (“Ethernet”) or the like. The NIC 1322 can also comprise any suitable wireless network interface controller capable of wirelessly connecting and communicating with other devices or computing nodes on the system 100. For example, the NIC 1322 can operate in accordance with any of a variety of wireless communication protocols, including for example, the IEEE 802.11 (“Wi-Fi”) protocol, the IEEE 802.16 or 802.20 (“WiMAX”) protocols, the IEEE 802.15.4a (“Zigbee”) protocol, the 802.15.3c (“UWB”) protocol, or the like.

The computing device 1300 can be connected to a mass storage device 1328 that provides non-volatile storage, for example a memory, for the computer. The mass storage device 1328 can store system programs, application programs, other program modules, and data, which have been described in greater detail herein. The mass storage device 1328 can be connected to the computing device 1300 through a storage controller 1324 connected to the chipset 1306. The mass storage device 1328 can consist of one or more physical storage units. A storage controller 1324 can interface with the physical storage units through a serial attached SCSI (SAS) interface, a serial advanced technology attachment (SATA) interface, a fiber channel (FC) interface, or other type of interface for physically connecting and transferring data between computers and physical storage units.

The computing device 1300 can store data on a mass storage device 1328 by transforming the physical state of the physical storage units to reflect the information being stored. The specific transformation of a physical state can depend on various factors and on different implementations of this description. Examples of such factors can comprise, but are not limited to, the technology used to implement the physical storage units and whether the mass storage device 1328 is characterized as primary or secondary storage or the like.

For example, the computing device 1300 can store information to the mass storage device 1328 by issuing instructions through a storage controller 1324 to alter the magnetic characteristics of a particular location within a magnetic disk drive unit, the reflective or refractive characteristics of a particular location in an optical storage unit, or the electrical characteristics of a particular capacitor, transistor, or other discrete component in a solid-state storage unit. Other transformations of physical media are possible without departing from the scope and spirit of the present description, with the foregoing examples provided only to facilitate this description. The computing device 1300 can read information from the mass storage device 1328 by detecting the physical states or characteristics of one or more particular locations within the physical storage units.

In addition to the mass storage device 1328 described herein, the computing device 1300 can have access to other computer-readable storage media to store and retrieve information, such as program modules, data structures, or other data. It should be appreciated by those skilled in the art that computer-readable storage media can be any available media that provides for the storage of non-transitory data and that can be accessed by the computing device 1300.

By way of example and not limitation, computer-readable storage media can comprise volatile and non-volatile, non-transitory computer-readable storage media, and removable and non-removable media implemented in any method or technology. However, as used herein, the term computer-readable storage media does not encompass transitory computer-readable storage media, such as signals. Computer-readable storage media includes, but is not limited to, RAM, ROM, erasable programmable ROM (“EPROM”), electrically erasable programmable ROM (“EEPROM”), flash memory or other solid-state memory technology, compact disc ROM (“CD-ROM”), digital versatile disk (“DVD”), high definition DVD (“HD-DVD”), BLU-RAY, or other optical storage, magnetic cassettes, magnetic tape, magnetic disk storage, other magnetic storage devices, or any other non-transitory medium that can be used to store the desired information in a non-transitory fashion.

A mass storage device, such as the mass storage device 1328 depicted in FIG. 13, can store an operating system utilized to control the operation of the computing device 1300. The operating system can comprise a version of the LINUX operating system. The operating system can comprise a version of the WINDOWS SERVER operating system from the MICROSOFT Corporation. According to additional aspects, the operating system can comprise a version of the UNIX operating system. Various mobile phone operating systems, such as IOS and ANDROID, can also be utilized. It should be appreciated that other operating systems can also be utilized. The mass storage device 1328 can store other system or application programs and data utilized by the computing device 1300.

The mass storage device 1328 or other computer-readable storage media can also be encoded with computer-executable instructions, which, when loaded into the computing device 1300, transforms the computing device from a general-purpose computing system into a special-purpose computer capable of implementing the aspects described herein. These computer-executable instructions transform the computing device 1300 by specifying how the CPU(s) 1304 transition between states, as described herein. The computing device 1300 can have access to computer-readable storage media storing computer-executable instructions, which, when executed by the computing device 1300, can perform the methods described in relation to FIGS. 1-12.

A computing device, such as the computing device 1300 depicted in FIG. 13, can also comprise an input/output controller 1332 for receiving and processing input from a number of input devices, such as a keyboard, a mouse, a touchpad, a touch screen, an electronic stylus, or other type of input device. Similarly, an input/output controller 1332 can provide output to a display, such as a computer monitor, a flat-panel display, a digital projector, a printer, a plotter, or other type of output device. It will be appreciated that the computing device 1300 may not comprise all of the components shown in FIG. 13, can comprise other components that are not explicitly shown in FIG. 13, or can utilize an architecture completely different than that shown in FIG. 13.

As described herein, a computing device can be a physical computing device, such as the computing device 1300 of FIG. 13. A computing device can also comprise a virtual machine host process and one or more virtual machine instances. Computer-executable instructions can be executed by the physical hardware of a computing device indirectly through interpretation and/or execution of instructions stored and executed in the context of a virtual machine.

It is to be understood that the methods and systems described herein are not limited to specific methods, specific components, or to particular implementations. It is also to be understood that the terminology used herein is not intended to be limiting.

As used in the specification and the appended claims, the singular forms “a,” “an,” and “the” comprise plural referents unless the context clearly dictates otherwise. Ranges can be expressed herein as from “about” one particular value, and/or to “about” another particular value. When such a range is expressed, another example can comprise from the one particular value and/or to the other particular value. It will be further understood that the endpoints of each of the ranges are significant both in relation to the other endpoint, and independently of the other endpoint.

“Optional” or “optionally” means that the subsequently described event or circumstance may or may not occur, and that the description comprises instances where said event or circumstance occurs and instances where it does not.

Throughout the description and claims of this specification, the word “comprise” and variations of the word, such as “comprising” and “comprises,” means “including but not limited to,” and is not intended to exclude, for example, other components, integers, or steps. “Exemplary” means “an example of.” “Such as” is not used in a restrictive sense, but for explanatory purposes.

Components and devices are described that can be used to perform the described methods and systems. When combinations, subsets, interactions, groups, etc., of these components are described, it is understood that while specific references to each of the various individual and collective combinations and permutations of these may not be explicitly described, each is specifically contemplated and described herein, for all methods and systems. This applies to all aspects of this application including, but not limited to, operations in described methods. Thus, if there are a variety of additional operations that can be performed it is understood that each of these additional operations can be performed with any combination of the described methods.

As will be appreciated by one skilled in the art, the methods and systems can take the form of entirely hardware, entirely software, or a combination of software and hardware aspects. Furthermore, the methods and systems can take the form of a computer program product on a computer-readable storage medium having computer-readable instructions, for example, computer software or program code, embodied in the storage medium. More particularly, the present methods and systems can take the form of web-implemented computer software. Any suitable computer-readable storage medium can be utilized including hard disks, CD-ROMs, optical storage devices, or magnetic storage devices.

The methods and systems are described above with reference to block diagrams and flowcharts of methods, systems, apparatuses, and computer program products. It will be understood that each block of the block diagrams and flowcharts, and combinations of blocks in the block diagrams and flowcharts, respectively, can be implemented by computer program instructions. These computer program instructions can be loaded on a general-purpose computer, special-purpose computer, or other programmable data processing apparatus to produce a machine, such that the instructions which execute on the computer or other programmable data processing apparatus create a means for implementing the functions specified in the flowchart block or blocks.

These computer program instructions can also be stored in a computer-readable memory that can direct a computer or other programmable data processing apparatus to function in a particular manner, such that the instructions stored in the computer-readable memory produce an article of manufacture including computer-readable instructions for implementing the function specified in the flowchart block or blocks. The computer program instructions can also be loaded onto a computer or other programmable data processing apparatus to cause a series of operational steps to be performed on the computer or other programmable apparatus to produce a computer-implemented process such that the instructions that execute on the computer or other programmable apparatus provide steps for implementing the functions specified in the flowchart block or blocks.

The various features and processes described herein can be used independently of one another or can be combined in various ways. All possible combinations and sub-combinations are intended to fall within the scope of this disclosure. In addition, certain methods or process blocks can be omitted in some implementations. The methods and processes described herein are also not limited to any particular sequence, and the blocks or states relating thereto can be performed in other sequences that are appropriate. For example, described blocks or states can be performed in an order other than that specifically described, or multiple blocks or states can be combined in a single block or state. The example blocks or states can be performed in serial, in parallel, or in some other manner. Blocks or states can be added or removed. The example systems and components described herein can be configured differently than described. For example, elements can be added to, removed from, or rearranged.

It will also be appreciated that various items are shown as being stored in memory or on storage while being used, and that these items or portions thereof can be transferred between memory and other storage devices for purposes of memory management and data integrity. Alternatively, some or all of the software modules and/or systems can execute in memory on another device and communicate with the shown computing systems via inter-computer communication. Furthermore, some or all of the systems and/or modules can be implemented or provided in other ways, such as at least partially in firmware and/or hardware, including, but not limited to, one or more application-specific integrated circuits (“ASICs”), standard integrated circuits, controllers, for example, executing appropriate instructions and including microcontrollers and/or embedded controllers, field-programmable gate arrays (“FPGAs”), complex programmable logic devices (“CPLDs”), etc. Some or all of the modules, systems, and data structures can also be stored, for example, as software instructions or structured data, on a computer-readable medium, such as a hard disk, a memory, a network, or a portable media article to be read by an appropriate device or via an appropriate connection. The systems, modules, and data structures can also be transmitted as generated data signals, for example, as part of a carrier wave or other analog or digital propagated signal, on a variety of computer-readable transmission media, including wireless-based and wired/cable-based media, and can take a variety of forms, for example, as part of a single or multiplexed analog signal, or as multiple discrete digital packets or frames. Such computer program products can also take other forms. Accordingly, the present invention can be practiced with other computer system configurations.

While the methods and systems have been described in connection with specific examples, it is not intended that the scope be limited to the specific examples set forth.

Unless otherwise expressly stated, it is in no way intended that any method set forth herein be construed as requiring that its operations be performed in a specific order. Accordingly, where a method claim does not actually recite an order to be followed by its operations or it is not otherwise specifically stated in the claims or descriptions that the operations are to be limited to a specific order, it is no way intended that an order be inferred, in any respect. This holds for any possible non-express basis for interpretation, including matters of logic with respect to arrangement of steps or operational flow and the plain meaning derived from grammatical organization or punctuation.

It will be apparent to those skilled in the art that various modifications and variations can be made without departing from the scope or spirit of the present disclosure. Alternatives will be apparent to those skilled in the art from consideration of the specification and practices described herein. It is intended that the specification and example figures be considered as exemplary only, with a true scope and spirit being indicated by the following claims.

### Aspects

The following Aspects are illustrative only and do not limit the scope of the present disclosure or the appended claims. Any part or parts of any one or more Aspects can be combined with any part or parts of any one or more other Aspects.

Aspect 1. A method, comprising: receiving, at a user interface, at least one user selection associated with cell staining; determining, based on the at least one user selection, a staining agent of a plurality of staining agents associated with staining a first portion of a cell; determining, based on the user selection of the staining agent, a first simulated view of a cell stained with the staining agent, wherein a component of the cell is shown in a color; displaying, based on the staining agent, a first emission spectrum associated with the staining agent; and displaying, at the user interface, at least one of the first simulated view of the cell and the first emission spectrum associated with the first simulated view of the cell.

Aspect 2. The method of Aspect 1, comprising displaying, at the user interface, the first simulated view of the stained cell and the first emission spectrum associated with the first simulated view of the stained cell.

Aspect 3. The method of any one of Aspects 1-2, wherein the at least one user selection further comprises any one or more of: a cell preparation type associated with the at least one user selection; a cell structure of interest associated with the at least one user selection; a product type associated with the at least one user selection; and an emission channel associated with the at least one user selection.

Aspect 4. The method of any one of Aspects 1-3, wherein the cell preparation type comprises any one or more of a live cell, a fixed cell, a fixed/retained cell, and a tissue.

Aspect 5. The method of any one of Aspects 1-4, wherein the cell structure comprises any one or more of a nucleus, actin, endoplasmic reticulum, mitochondria, lysosome, and a cell membrane.

Aspect 6. The method of any one of Aspects 1-5, wherein the product type comprises any one or more of a dye, a reporter, an antibody, and a plate reader.

Aspect 7. The method of any one of Aspects 1-6, wherein the emission channel comprises an emission spectrum associated with the product type.

Aspect 8. The method of any one of Aspects 1-7, wherein the at least one user selection is a first user selection, the method further comprising receiving at least one second user selection associated with cell staining; determining, based on the at least one second user selection, a second product associated with staining a second portion of the cell; determining, based on the second product, a second simulated view of the stained cell, wherein the second simulated view of the stained cell comprises a second portion of the cell highlighted in a second color; determining, based on the second product, a second emission spectrum associated with the second product and the second color; displaying, at the user interface, a composite simulated view of the stained cell comprising the first simulated view of the stained cell and the second simulated view of the stained cell; and displaying, at the user interface, a composite emission spectrum comprising the first emission spectrum and the second emission spectrum.

Aspect 9. The method of any one of Aspects 1-8, further comprising: determining a threshold similarity between the first emission spectrum associated with the first user selection and the second emission spectrum associated with the second user selection; and displaying a message associated with the threshold similarity.

Aspect 10. The method of any one of Aspects 1-9, further comprising: determining a threshold similarity between the first emission spectrum associated with the first user selection and the second emission spectrum associated with the second user selection; and preventing displaying, at the user interface, the composite simulated view of the stained cell and the composite emission spectrum.

Aspect 11. The method of any one of Aspects 1-10, wherein the at least one user selection comprises an indication of an assay type, further comprising: determining one or more products associated with the assay type; and displaying, at the user interface, the one or more products associated with the assay type.

Aspect 12. The method of any one of Aspects 1-11, wherein the at least one user selection comprises a selection of a cell paint dye, further comprising: displaying, at the user interface, a general emission spectrum associated with the selected cell paint dye; and displaying, at the user interface, one or more products associated with the cell paint dye.

Aspect 13. The method of any one of Aspects 1-12, wherein the first user selection and the second user selection are received from a first user, further comprising: updating, based on the first user selection and the second user selection, a relationship between the first product and the second product; receiving, from a second user, a third user selection associated with the first product; and displaying, at the user interface, an indication of the second product and an indication of an association between the first product and the second product.

Aspect 14. The method of any one of Aspects 1-13, wherein the displaying the composite simulated view of the stained cell further comprises adjusting, based on at least one of the first product and the second product, a depiction of the composite simulated view of the stained cell.

Aspect 15. The method of any one of Aspects 1-14, further comprising: receiving a user selection of an emission threshold cutoff; and presenting, at the user interface, at least one product of the plurality of products that satisfies the emission threshold cutoff.

Aspect 16. The method of any one of Aspects 1-15, further comprising: receiving, at the user interface, another user selection, wherein the another user selection is associated with purchasing the staining agent; and based on the receiving the another user selection, presenting a different user interface associated with processing a sale of the staining agent.

Aspect 17. A computing device, comprising: one or more processors; and memory storing instructions that, when executed by the one or more processors, cause the computing device to: receive, at a user interface associated with the computing device, at least one user selection associated with cell staining; determine, based on the at least one user selection, a first product associated with staining a first portion of a cell; determine, based on the user selection of the first product, a first simulated view of a stained cell stained with the first product, wherein the first simulated view of the stained cell comprises a portion of the cell highlighted in a particular color; determine, based on the first product, a first emission spectrum associated with the first product and the particular color; and display, at the user interface associated with the computing device, at least one of the first simulated view of the stained cell and the first emission spectrum associated with the first simulated view of the stained cell.

Aspect 18. The computing device of Aspect 17, wherein the instructions, when executed, cause the computing device to display, at the user interface, the first simulated view of the stained cell and the first emission spectrum associated with the first simulated view of the stained cell.

Aspect 19. The computing device of any one of Aspects 17-18, wherein the at least one user selection further comprises one or more of: a cell preparation type associated with the at least one user selection; a cell structure of interest associated with the at least one user selection; a product type associate with the at least one user selection; and an emission channel associated with the at least one user selection.

Aspect 20. The computing device of any one of Aspects 17-19, wherein the instructions, when executed, cause the computing device to: receive, at the user interface, another user selection, wherein the another user selection is associated with purchasing the staining agent; and based on the receiving the another user selection, present a different user interface associated with processing a sale of the staining agent.

Aspect 21. The computing device of any one of Aspects 17-20, wherein the cell preparation type comprises any one or more of a live cell, a fixed cell, a fixed/retained cell, and a tissue.

Aspect 22. The computing device of any one of Aspects 17-21, wherein the cell structure comprises any one or more of a nucleus, actin, endoplasmic reticulum, mitochondria, lysosome, and a cell membrane.

Aspect 23. The computing device of any one of Aspects 17-22, wherein the product type comprises any one or more of a dye, a reporter, an antibody, and a plate reader.

Aspect 24. The computing device of any one of Aspects 17-23, wherein the emission channel comprises an emission spectrum associated with the product type.

Aspect 25. The computing device of any one of Aspects 17-24, wherein the at least one user selection is a first user selection, and wherein the instructions, when executed, further cause the device to: receive at least one second user selection associated with cell staining; determine, based on the at least one second user selection, a second product associated with staining a second portion of the cell; determine, based on the second product, a second simulated view of the stained cell, wherein the second simulated view of the stained cell comprises a second portion of the cell highlighted in a second color; determine, based on the second product, a second emission spectrum associated with the second product and the second color; display, at the user interface associated with the computing device, a composite view of the stained cell comprising the first simulated view of the stained cell and the second simulated view of the stained cell; and display, at the user interface associated with the computing device, a composite emission spectrum comprising the first emission spectrum and the second emission spectrum.

Aspect 26. The computing device of any one of Aspects 17-25, wherein the instructions, when executed, further cause the device to: determine a threshold similarity between the first emission spectrum associated with the first user selection and the second emission spectrum associated with the second user selection; and display a message associated with the threshold similarity.

Aspect 27. The computing device of any one of Aspects 17-26, wherein the instructions, when executed, further cause the device to: determine a threshold similarity between the first emission spectrum associated with the first user selection and the second emission spectrum associated with the second user selection; and prevent display, at the user interface associated with the computing device, the composite simulated view of the stained cell and the composite emission spectrum.

Aspect 28. The computing device of any one of Aspects 17-27, wherein the at least one user selection comprises an indication of an assay type, and wherein the instructions, when executed, further cause the device to: determine one or more products associated with the assay type; and display, at the user interface associated with the computing device, the one or more products associated with the assay type.

Aspect 29. The computing device of any one of Aspects 17-28, wherein the at least one user selection comprises a selection of a cell paint dye, and wherein the instructions, when executed, further cause the device to: display, at the user interface associated with the computing device, a general emission spectrum associated with the selected cell paint dye; and display, at the user interface associated with the computing device, one or more products associated with the cell paint dye.

Aspect 30. The computing device of any one of Aspects 17-29, wherein the first user selection and the second user selection are received from a first user, and wherein the instructions, when executed, further cause the device to: update, based on the first user selection and the second user selection, a relationship between the first product and the second product; receive, from a second user, a third user selection associated with the first product; and display, at the user interface associated with the computing device, an indication of the second product and an indication of an association between the first product and the second product.

Aspect 31. The computing device of any one of Aspects 17-30, wherein causing the computing device to display the composite simulated view of the stained cell further comprises causing the computing device to adjust, based on at least one of the first product and the second product, a depiction of the composite simulated view of the stained cell.

Aspect 32. The computing device of any one of Aspects 17-31, wherein the instructions, when executed, further cause the device to: receive a user selection of an emission threshold cutoff; and present, at the user interface, at least one product of the plurality of products that satisfies the emission threshold cutoff.

What is claimed:

1. A method, comprising:
receiving, at a user interface, at least one user selection associated with cell staining;
determining, based on the at least one user selection, a staining agent of a plurality of staining agents associated with staining a first portion of a cell;
determining, based on the user selection of the staining agent, a first simulated view of a cell stained with the staining agent, wherein a component of the cell is shown in a color;
displaying, based on the staining agent, a first emission spectrum associated with the staining agent; and
displaying, at the user interface, at least one of the first simulated view of the cell and the first emission spectrum associated with the first simulated view of the cell.

2. The method of claim 1, comprising displaying, at the user interface, the first simulated view of the cell and the first emission spectrum associated with the first simulated view of the cell.

3. The method of claim 1, wherein the at least one user selection further comprises any one or more of:
a cell preparation type associated with the at least one user selection;
a cell structure of interest associated with the at least one user selection;
a product type associated with the at least one user selection; and
an emission channel associated with the at least one user selection.

4. The method of claim 3, wherein the cell preparation type comprises any one or more of a live cell, a fixed cell, a fixed/retained cell, and a tissue.

5. The method of claim 3, wherein the cell structure comprises any one or more of a nucleus, actin, endoplasmic reticulum, mitochondria, lysosome, and a cell membrane.

6. The method of claim 3, wherein the product type comprises any one or more of a dye, a reporter, an antibody, and a plate reader.

7. The method of claim 3, wherein the emission channel comprises an emission spectrum associated with the product type.

8. The method of claim 1, wherein the at least one user selection is a first user selection, the method further comprising receiving at least one second user selection;
determining, based on the at least one second user selection, a second staining agent associated with staining a second portion of the cell;
determining, based on the second staining agent, a second simulated view of the cell, wherein a second component of the cell is shown in a second color;
determining, based on the second staining agent, a second emission spectrum associated with the second staining agent and the second color;
displaying, at the user interface, a composite simulated view of the cell comprising the first simulated view of the cell and the second simulated view of the cell; and
displaying, at the user interface, a composite emission spectrum comprising the first emission spectrum and the second emission spectrum.

9. The method of claim 8, further comprising:
determining a threshold similarity between the first emission spectrum associated with the first user selection and the second emission spectrum associated with the second user selection; and
displaying a message associated with the threshold similarity.

10. The method of claim 8, further comprising:
determining a threshold similarity between the first emission spectrum associated with the first user selection and the second emission spectrum associated with the second user selection; and
preventing displaying, at the user interface, the composite simulated view of the cell and the composite emission spectrum.

11. The method of claim 1, wherein the at least one user selection comprises an indication of an assay type, further comprising:
determining one or more products associated with the assay type; and
displaying, at the user interface, the one or more products associated with the assay type.

12. The method of claim 1, wherein the at least one user selection comprises a selection of a cell paint dye, further comprising:
displaying, at the user interface, a general emission spectrum associated with the selected cell paint dye; and
displaying, at the user interface, one or more products associated with the cell paint dye.

13. The method of claim 8, wherein the first user selection and the second user selection are received from a first user, further comprising:
updating, based on the first user selection and the second user selection, a relationship between the first staining agent and the second staining agent;
receiving, from a second user, a third user selection associated with the first staining agent; and
displaying, at the user interface, an indication of the second staining agent and an indication of an association between the first staining agent and the second staining agent.

14. The method of claim 8, wherein the displaying the composite simulated view of the cell further comprises adjusting, based on at least one of the first staining agent and the second staining agent, a depiction of the composite simulated view of the cell.

15. The method of claim 1, further comprising:
receiving a user selection of an emission threshold cutoff; and
presenting, at the user interface, at least one staining agent of the plurality of staining agents that satisfies the emission threshold cutoff.

16. The method of claim 1, further comprising:
receiving, at the user interface, another user selection, wherein the another user selection is associated with purchasing the staining agent; and
based on the receiving the another user selection, presenting a different user interface associated with processing a sale of the staining agent.

17. A computing device, comprising:
one or more processors; and
memory storing instructions that, when executed by the one or more processors, cause the computing device to:
receive, at a user interface associated with the computing device, at least one user selection associated with cell staining;
determine, based on the at least one user selection, a first product associated with staining a first portion of a cell;
determine, based on the user selection of the first product, a first simulated view of a stained cell stained with the first product, wherein the first simulated view of the stained cell comprises a portion of the cell highlighted in a particular color;
determine, based on the first product, a first emission spectrum associated with the first product and the particular color; and
display, at the user interface associated with the computing device, at least one of the first simulated view of the stained cell and the first emission spectrum associated with the first simulated view of the stained cell.

18. The computing device of claim 17, wherein the instructions, when executed, cause the computing device to display, at the user interface, the first simulated view of the cell and the first emission spectrum associated with the first simulated view of the cell.

19. The computing device of claim 17, wherein the at least one user selection further comprises one or more of:
a cell preparation type associated with the at least one user selection;
a cell structure of interest associated with the at least one user selection;
a product type associate with the at least one user selection; and
an emission channel associated with the at least one user selection.

20. The computing device of claim 17, wherein the instructions, when executed, cause the computing device to:
receive, at the user interface, another user selection, wherein the another user selection is associated with purchasing the staining agent; and
based on the receiving the another user selection, present a different user interface associated with processing a sale of the staining agent.
